(19) United States
(12) Patent Application Publication
(10) Pub. No.: US 2007/0138484 A1
(43) Pub. Date: Jun. 21, 2007

(54) LIGHT-EMITTING DEVICE AND METHOD OF MANUFACTURING THE SAME

(76) Inventors: Masahiro Yamamoto, Kawasaki-shi (JP); Yasushi Hattori, Kawasaki-shi (JP); Naomi Shida, Tokyo (JP); Kei Kaneko, Yokohama-shi (JP); Genichi Hatakoshi, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/561,670

(22) Filed: Nov. 20, 2006

(30) Foreign Application Priority Data
Dec. 16, 2005 (JP) 2005-363625

(51) Int. Cl. H01L 33/00

(52) U.S. Cl. 257/79

(57) ABSTRACT

A light-emitting device is provided, which includes a substrate, a light-emitting element configured to emit light having a first wavelength, the light-emitting element having a pair of electrodes and being formed above the substrate, a metal layer interposed between the substrate and the light-emitting element and having a planar configuration, and a wavelength converting layer formed on the metal layer. The periphery of the metal layer is at least partially constituted by a plurality of projected portions and a plurality of recessed portions. The plurality of projected portions locates outside of the light-emitting element. The wavelength converting layer absorbs at least part of the light emitted from the light-emitting element and converts the first wavelength, thereby light having a second wavelength differing in wavelength from the first wavelength is emitted.

### CROSS-REFERENCE TO RELATED APPLICATIONS

This application is based upon and claims the benefit of priority from prior Japanese Patent Application No. 2005-363625, filed Dec. 16, 2005, the entire contents of which are incorporated herein by reference.

### BACKGROUND OF THE INVENTION

1. Field of the Invention

This invention relates to a light-emitting device comprising a combination of a semiconductor light-emitting element and a fluorescent substance, and to a method of manufacturing the light-emitting device.

2. Description of the Related Art

In recent years, much attention has been paid to a small white LED where a semiconductor light-emitting element such as a blue LED, a violet LED, a UV LED, etc., is employed as an excitation light source. In this white LED, part or all of the emission from a semiconductor light-emitting element is converted so as to enable the white LED to emit white light.

The light-emitting device comprising a combination of a semiconductor light-emitting element and a fluorescent substance can be utilized in various fields as an illuminating source, a liquid crystal back-light source, etc. This light-emitting device can be manufactured by a procedure wherein a fluorescent substance is incorporated into a raw material for a light-transmitting member such for example as silicone resin, glass, etc., to obtain a mixture, which is dripped into a concaved portion having a light-transmitting element mounted thereon and then thermally cured, thus obtaining this light-emitting device. On the other hand, in the case of an LED chip where a semiconductor substrate in constituted by GaN, etc., it is constructed such that the light-emitting element thereof is lead out by a conductive wire from the electrodes mounted on the upper surface of the LED chip.

Generally, since the specific gravity of a fluorescent substance is larger than that of a sealing resin, the fluorescent substance precipitates in the course of thermally curing the resin after the fluorescent substance has been mixed with the sealing resin, thereby making it impossible to uniformly distribute the fluorescent substance into the sealing resin. The non-uniform density distribution of fluorescent substance may cause uneven emission of light.

Further, since the LED element acting as an excitation light source has a predetermined emission pattern, a non-uniform density distribution of fluorescent substance may further increase possibilities of uneven emission of the light that will be generated from the fluorescent substance in the illumination region of the LED element.

For these reasons, it has been considered necessary, in order to employ the LED element for illumination, to mount a specific lens system which is matched with a specific kind of LED element. However, these attempts to obtain a desired chromaticity and an emission intensity will lead not only to an increase in manufacturing cost but also to the occurrence of various problems with respect to the performance of light-emitting device.

### BRIEF SUMMARY OF THE INVENTION

A light-emitting device according to one aspect of the present invention comprises a substrate; a light-emitting element configured to emit light having a first wavelength, the light-emitting element having a pair of electrodes and being formed above the substrate; a metal layer interposed between the substrate and the light-emitting element and having a planar configuration, a periphery of which is at least partially constituted by a plurality of projected portions and a plurality of recessed portions, the plurality of projected portions being located outside of the light-emitting element; and a wavelength converting layer formed on the metal layer, the wavelength converting layer absorbing at least part of the light emitted from the light-emitting element and converting the first wavelength, thereby light having a second wavelength differing in wavelength from the first wavelength being emitted.

A light-emitting device according to another aspect of the present invention comprises a substrate; a light-emitting element configured to emit light having a first wavelength and accompanied with a far-field pattern and a near-field pattern, the light-emitting element having a pair of electrodes and being formed above the substrate; a metal layer interposed between the substrate and the light-emitting element and having a planar configuration, the periphery of which is at least partially constituted by a pattern corresponding to the far-field pattern or the near-field pattern of the light emitted from the light-emitting element; and a wavelength converting layer formed on the metal layer, the wavelength converting layer absorbing at least part of the light emitted from the light-emitting element and converting the first wavelength, thereby light having a second wavelength differing in wavelength from the first wavelength being emitted.

A method for manufacturing a light-emitting device according to a further aspect of the present invention comprises forming a metal layer on a substrate; working the metal layer to form a patterned metal layer having a planar configuration, a periphery of which is at least partially constituted by a plurality of projected portions and a plurality of recessed portions; mounting a light-emitting element at a center of the patterned metal layer, the light-emitting element being configured to emit light having a first wavelength; dripping a raw material containing fluorescent substance from over the light-emitting element to selectively form a wavelength converting layer on the surfaces of the patterned metal layer and the light-emitting element or on the surface of the patterned metal layer, the wavelength converting layer absorbing at least part of the light emitted from the light-emitting element and converting the first wavelength, thereby light having a second wavelength differing in wavelength from the first wavelength being emitted.

### BRIEF DESCRIPTION OF THE SEVERAL VIEWS OF THE DRAWING

FIGS. 1A and 1B represent respectively a cross-sectional view illustrating the structure of a white LED according to a first embodiment;

FIGS. 2A and 2B represent respectively a top plan view illustrating the LED chip 3 of FIG. 1A and the arrangement of an electrode below the LED chip;

FIGS. 3A and 3B represent respectively a cross-sectional view illustrating the structure of an LED chip;

FIG. 4 represents a top plan view illustrating the LED chip according to a second embodiment and the arrangement of an electrode below the LED chip;

FIGS. 5A and 5B represent respectively a top plan view illustrating the LED chip according to a third embodiment and the arrangement of an electrode below the LED chip;

FIGS. 6A and 6B represent respectively a top plan view illustrating the LED chip according to a fourth embodiment and the arrangement of an electrode below the LED chip;

FIG. 7 represents a cross-sectional view illustrating the structure of a white LED according to a fifth embodiment;

FIGS. 8A and 8B represent respectively a top plan view illustrating the LED chip according to a sixth embodiment and the arrangement of an electrode below the LED chip; and

FIGS. 9A to 9D represent respectively a top plan view illustrating the LED chip according to an eighth embodiment, the arrangement of an electrode (fluorescent layer) below the LED chip, and the direction of lead-out of bonding wire 5 relative to the LED chip.

### DETAILED DESCRIPTION OF THE INVENTION

Next, embodiments of the present invention will be explained in detail with reference to the drawings.

### First Embodiment

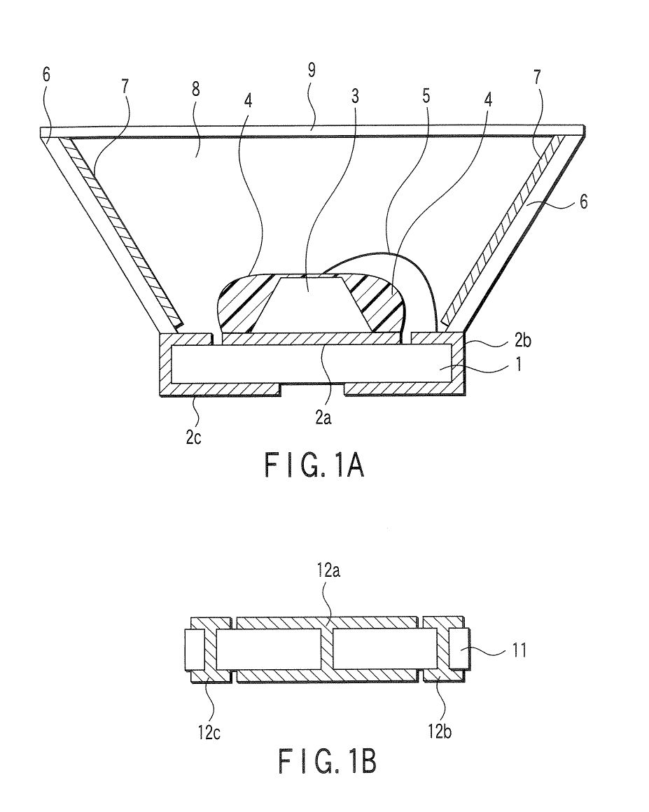

As shown in FIG. 1A, a circular mounting substrate 1 is provided, on the upper surface thereof, with electrodes 2a, 2b and 2c, wherein the electrodes 2b and 2c are extended, through the side of the mounting substrate 1, to the bottom surface of the mounting substrate 1. This structure can be fabricated by bending the electrodes 2b and 2c, which have been attached to the upper surface of the mounting substrate 1, along the side and bottom surface of the mounting substrate 1.

On the electrode 2a formed on the upper surface of mounting substrate 1 is disposed an LED chip 3. As an example of this LED chip 3, it is possible to employ a semiconductor light-emitting element (such as a gallium nitride-based semiconductor light-emitting element) emitting a light of wavelength ranging in color, for example, from blue to ultraviolet (for example, a light having a wavelength ranging from 400 to 550 nm). The occupying area of this LED chip 3 is smaller than that of the electrode 2a, so that a peripheral portion of the electrode 2a exposes from the periphery of the LED chip 3. An electrode (not shown) formed on the upper surface of the LED chip 3 is electrically connected with the electrode 2b by a bonding wire 5. Incidentally, the side of the LED chip 3 is obliquely worked on the occasion of forming the LED chip 3 in order to improve the light-retrieving efficiency.

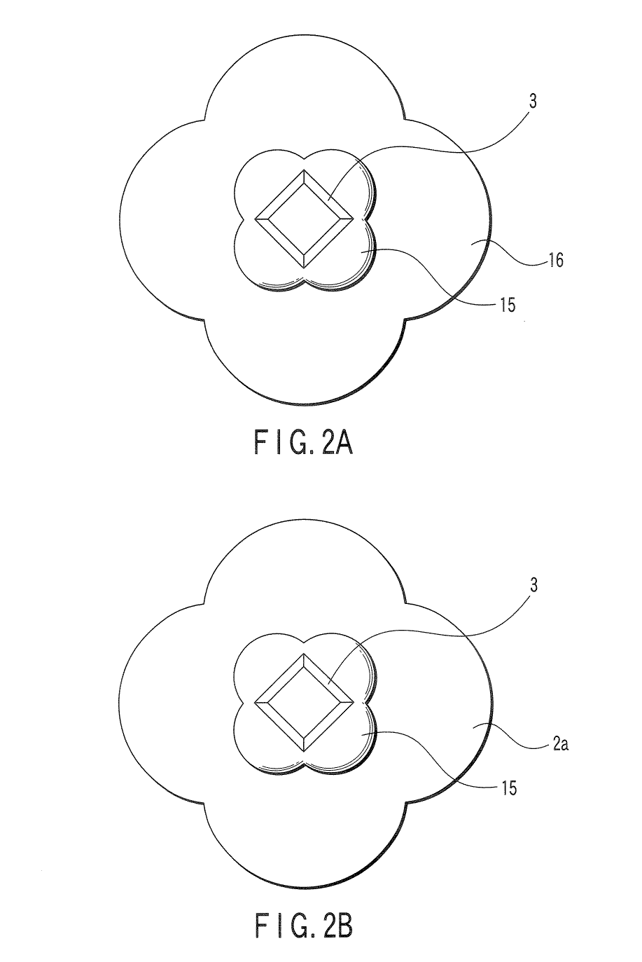

As shown in FIGS. 2A and 2B, the planar configuration of the electrode 2a is made to correspond with a far-field pattern 16 of the light which is emitted from the upper surface and four sides of the LED chip 3. Namely, the electrode 2a has a planar configuration, the periphery of which being partially constituted by four projected portions and four recessed portions formed to surround the LED chip 3. The pattern of each of the projected portions is made to correspond with the pattern of far-field pattern 16. In this case, the planar configuration of the electrode 2a is provided with projected portions each corresponding with each of four apexes of the planar configuration of the LED chip 3. Each of these projected portions is formed to have a nearly parabolic or arc-like profile. In order to make the configuration of the electrode 2a correspond with the configuration of the far-field pattern, the electrode 2a is made larger than the LED chip 3. Specifically, the electrode 2a may be designed to have a size (a distance between the opposite apexes of the parabolic or arc-like profile) which is about 1 to 10 times as large as the outer diameter (in the diagonal direction) of the LED chip 3.

Incidentally, a portion indicated by the reference numeral 15 corresponds with a near-field pattern of the light to be emitted from the upper surface and four sides of the LED chip 3. This near-field pattern 15 is provided with projected portions corresponding respectively with each of four sides in the planar configuration of the LED chip 3. Each of these projected portions is formed to have nearly a parabolic or arc-like profile.

As shown in FIG. 1A, a fluorescent layer 4 as a wavelength converting layer is selectively formed in contact with an upper surface portion of the electrode 2a which is exposed around the LED chip 3 and also in contact with the sides of the LED chip 3. Although this fluorescent layer 4 is formed on the upper surface of the electrode 2a, this fluorescent layer 4 is not formed on a upper surface portion of the mounting substrate 1 which is located outside the electrode 2a. Namely, the outer peripheral profile of the planar configuration of the fluorescent layer 4 is made substantially identical with the outer peripheral profile of the planar configuration of the electrode 2a. This planar configuration of the fluorescent layer 4 is created because of a difference in surface tension between the electrode 2a (metal) and the upper surface (mainly constituted by an insulating material) of the mounting substrate 1 relative to the fluorescent layer 4 (mainly constituted by a resin). This fact has been first found out by the present inventor as will be further discussed hereinafter.

A sidewall 6 having an inverted cone-shaped sidewall gradually expanding toward a top opening is extended upward from the periphery of the mounting substrate 1, thereby forming a concave portion. The LED chip 3 is disposed on the circular bottom of the concave portion. On the inner peripheral surface of the sidewall 6 is attached a reflection film 7 in such a manner that the reflection film 7 is electrically insulated from the electrodes 2a, 2b and 2c. The reflection film 7 may be omitted if desired. Further, a light-transmitting material may be embedded, if required, in the space 8 inside the concave portion. This light-transmitting material may be formed of a substance exhibiting excellent electrical insulating properties and having a property to transmit the light emitted from the LED chip 3. For example, this light-transmitting material may be formed of a material selected from glass and resin such as silicone resin, acrylic resin, epoxy resin, fluorinated resin, etc. A reference numeral 9 represents a cover plate to be employed for sealing the LED chip 3.

According to the white LED representing this embodiment, the LED chip 3 constituted, for example, by a gallium nitride-based semiconductor (which is constituted by nitrogen and an element selected from indium (In), gallium (Ga), aluminum (Al) and boron (B)) emits light having a wavelength ranging in color from blue to ultraviolet. Further, as this light is received by the fluorescent layer 4, this light is converted into a light having a different wavelength, which is then emitted from the fluorescent layer 4. By suitably combining these lights, it is possible to provide a light-emitting device emitting a substantially whitish light. This light-emitting device can be employed as an illumination light source which is excellent in reliability and has a long life. A white LED where an LED of high output is employed as an excitation source can be employed for substituting a fluorescent lamp or an incandescent lamp.

In particular, according to the white LED representing this embodiment, the planar configuration of the electrode 2a is formed to correspond with the far-field pattern 16 of the light to be emitted from the LED chip 3, and the planar configuration of the fluorescent layer 4 is formed to correspond with the planar configuration of the electrode 2a. Namely, since the planar configuration of the fluorescent layer 4 is formed to correspond with the far-field pattern 16, it is now possible to make the intensity distribution of the light emitted from the LED chip 3 correspond exactly with the density distribution of the fluorescent substance in the fluorescent layer 4. Thus, the fluorescent layer 4 can be disposed in a manner that the intensity distribution of the light emitted from the LED chip 3 can be reliably reflected, while inhibiting any wasting of light in the conversion of light. Therefore, it is possible to obtain a white LED which is negligible in non-uniformity of color and uniform in light-emitting pattern.

Next, the method of manufacturing the white LED according to this embodiment will be explained.

First of all, the LED chip 3 shown in FIG. 1A is manufactured. As this LED chip 3, a nitride-based semiconductor light-emitting element having, as a light-emitting layer, an In_{0.2}Ga_{0.8}N semiconductor layer where a monochromatic emission peak is of visible light (for example, 455 nm) is employed for instance. More specifically, this LED chip 3 can be fabricated by a procedure wherein trimethyl gallium (TMG) gas, trimethyl indium (TMI) gas, trimethyl aluminum (TMA) gas, nitrogen gas and a dopant gas are passed, together with a carrier gas, over a sapphire substrate that has been washed, thereby forming a film of nitride semiconductor by a MOCVD method. As the dopant gas, it is possible to employ SiH₄, etc., as an n-type dopant gas, and to employ Cp₂Mg (bis-cyclopentadienyl magnesium), etc. as a p-type dopant gas. By switching these dopant gases, it is possible to form layers that may be employed as an n-type nitride semiconductor or a p-type nitride semiconductor.

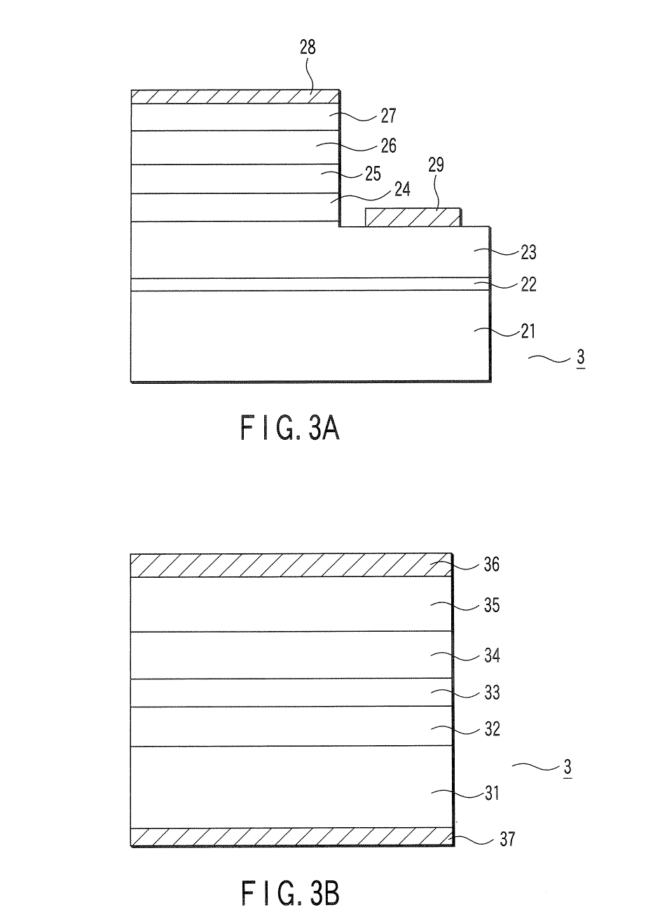

FIG. 3A illustrates the structure of an LED chip 3 wherein an insulating substrate such as a sapphire substrate is employed. FIG. 3B illustrates the structure of an LED chip 3 wherein a conductive substrate such as a GaN substrate or an SiC substrate is employed.

As shown in FIG. 3A, an n-type GaN layer 22 which is an undoped nitride semiconductor, a Si-doped GaN layer 23 to be used as an n-type contact layer, and an n-type GaN layer 24 (it may be an n-type AlGaN layer) which is an undoped nitride semiconductor are successively formed on a sapphire substrate 21. Then, a GaN layer to be employed as a barrier layer (six layers in total) and an InGaN layer to be employed as a barrier layer (five layers in total) are alternately laminated to form a light-emitting layer 25 having a multiple quantum well structure.

On this light-emitting layer 25 are further successively laminated, as a p-type clad layer, a Mg-doped p-type AlGaN layer 26 and, as a p-type contact layer, a Mg-doped p-type GaN layer 27. Then, the resultant structure is etched from the p-type contact layer 27 down to the n-type contact layer 23 to expose the surface of the n-type contact layer 23, on which an n-side electrode 29 is formed. Further, a p-side electrode 28 is formed on the p-type GaN layer 27.

The deposition of these electrodes can be achieved using a sputtering method, a vacuum deposition method, an electron beam deposition method, etc. Incidentally, as described above, it is preferable, for the convenience of forming these layers, to deposit a GaN layer 22 (or AlN layer) as a buffering layer on the sapphire substrate 21 at a low or high temperature. Finally, scribe lines are drawn on the semiconductor wafer thus fabricated and then split the wafer, thus manufacturing the LED chip 3. In this case, as described above, it is preferable, for the purpose of improving the light-retrieving efficiency, to work the chip when forming the chip so as to obtain the chip having oblique sides.

The LED chip 3 having a structure as shown in FIG. 3B can be manufactured in the same manner as described above. Namely, an n-type GaN layer 32 (which may be an n-type AlGaN layer) which is an undoped nitride semiconductor, a light-emitting layer 33 having a multiple quantum well structure, a p-type AlGaN layer 34 to be employed as a p-type clad layer, and a p-type GaN layer 35 to be used as a p-type contact layer are successively formed on an n-type substrate 31 such as a GaN substrate or of an SiC substrate. Then, a p-side electrode 36 is formed on the p-type contact layer 35 and an n-side electrode 37 is formed on the n-type substrate 31. The steps to be followed thereafter may be the same as those described above in the manufacture of the LED chip 3 of FIG. 3A. Incidentally, if a GaN substrate or an SiC substrate is to be employed, the employment of the aforementioned buffering layer is not imperative.

Then, the LED chip 3 thus manufactured by the aforementioned manufacturing steps is mounted on the mounting substrate 1 provided in advance with electrodes 2a, 2b and 2c. This LED chip 3 is fixed to the mounting substrate 1 using an eutectic solder (Au—Sn), a Pb—Sn solder, a lead-free solder, etc. As the material for the mounting substrate 1, it is preferable to employ a material which is almost the same in thermal expansion coefficient as the LED chip 3, thereby making it possible to alleviate a thermal stress that may be generated between the mounting substrate 1 and the LED chip 3.

For example, in the case where a gallium nitride-based semiconductor light-emitting element is employed as a semiconductor light-emitting element, it is preferable to employ aluminum nitride, boron nitride or diamond as the mounting substrate 1. When these materials are employed for the mounting substrate 1, it is also possible to enhance the heat-releasing effect thereof. Further, in order to enhance the heat-releasing effect, it is also possible to employ a Mg-based, Al-based or Cu-based metal core material which is capable exhibiting a heat conductivity of as high as 100 W/(m·K) or more. These materials may be molded into an approximately cubic structure by injection molding or press molding, thus enabling it to be employed in a package.

In this case, since it is required to secure the insulation between the electrodes as well as the insulation of the bottom of the concave portion, these materials may be embedded in the mounting substrate 1 for instance. However, these materials may not necessarily be restricted to any particular structure, so that the mounting substrate 1 may be constituted by a plastic board made of epoxy resin. Alternatively, the mounting substrate 1 may be formed using Si and the concave portion may be formed by etching, etc.

In the case where the LED chip 3 of FIG. 3A is employed, a pair of positive and negative lead electrodes are employed to correspond with the electrodes 2b and 2c, respectively, with the electrode 2a corresponding with the metallic member acting as a heat sink as shown in FIG. 1A. The p-side electrode 28 of the LED chip 3 is connected, via a bonding wire 5 made of Au, etc., with the electrode 2b. The n-side electrode 29 is connected, via a bonding wire (not shown), with the electrode 2c. On the other hand, in the case where the LED chip 3 of FIG. 3B is employed, a pair of positive and negative lead electrodes are employed to correspond with the electrodes 12b and 12a, respectively, with the electrode 12a acting also as a heat sink as shown in FIG. 1B. The electrode 12a is provided so as to penetrate the mounting substrate 1. The p-side electrode 36 of the LED chip 3 is connected, via a bonding wire 5, with the electrode 12b. The n-side electrode 37 is connected with the electrode 12a. The electrode 12c is formed integral with the electrode 12b. Incidentally, the structures shown in FIGS. 1A and 1B represent respectively only one example and hence it is needless to say that it is possible to employ any other structures as desired.

The mounting substrate 1 provided with the electrodes 2a, 2b and 2c can be manufactured according to the following method. First of all, a mold is installed for the aforementioned pair of positive and negative lead electrodes and for the heat sink. This mold is provided so as to sandwich the lead electrodes and heat sink from both sides thereof. Then, a molding resin is injected into the space enclosed by this mold and cured to form the mounting substrate 1. The sidewall 6 to be disposed on the outer peripheral portion of the mounting substrate 1 may be formed concurrent with the steps of injecting and curing the aforementioned resin. Alternatively, the sidewall 6 may be fabricated in a separate step.

In the case of the white LED shown in FIG. 1A, a pair of positive and negative lead electrodes are formed integral with the mounting substrate 1 with these lead electrodes being exposed at the bottom of the concave portion. These lead electrodes are provided respectively with an outer lead portion which is extended from the mounting substrate 1. These outer lead portions are bent inward at the side of mounting substrate 1 and the inwardly bent portions are soldered in a subsequent step.

Then, the fluorescent layer 4 is formed. This fluorescent layer 4 is formed of resin (light-transmitting material) such as silicone resin, acrylic resin, epoxy resin, etc., in which a fluorescent substance is incorporated. This fluorescent layer 4 can be formed as follows. First of all, oxides of yttrium (Y), gadolinium (Gd), aluminum (Al) and cerium (Ce) (it may be replaced by praseodymium (Pr)) are mixed together at a stoichiometric ratio to obtain a raw fluorescent substance. Alternatively, oxides of strontium (Sr) (it may be replaced by barium (Ba) or calcium (Ca)), silicon (Si) and europium (Eu) may be employed to obtain a raw fluorescent substance.

When oxides of Y, Gd, Al and Ce (it may be replaced by Pr) are employed as raw fluorescent substance, it is possible to obtain a fluorescent substance represented by YAG (yttrium aluminum garnet):Ce (Pr)(activating element) (for example, (Y, Gd)₃(Al, Gd)₅O₁₂:Ce). Further, when oxides of Sr (it may be replaced by Ba or Ca), Si and Eu are employed as raw fluorescent substance, it is possible to obtain an europium-activated alkaline earth metal silicate-based fluorescent substance represented by (Ba, Ca, Sr)₂SiO₄:Eu (activating element) (for example, (Sr_{1.84}Ba_{0.12})₂SiO₄:Eu).

These fluorescent substances are all yellow type fluorescent substances, so that when a blue-emitting LED chip is employed, it is possible to obtain a white light through color mixture, i.e., the mixing of a blue light emitted from this LED chip with a yellow light emitted from these fluorescent substances as these fluorescent substances receive the blue light. In the case of the latter fluorescent substance, part of oxygen (O) may be replaced by nitrogen (N). Further, it is also possible to employ a nitride where oxygen is entirely replaced by nitrogen.

The fluorescent raw substance thus obtained is mixed with a flux to obtain a mixture which is then placed in a crucible and subjected to a mixing process for two hours in a ball mill. After balls have been removed, the mixture was subjected to sintering in a weak reducing atmosphere for six hours at a temperature ranging from 1400 to 1600° C. and then to further sintering in a reducing atmosphere for six hours at a temperature ranging from 1400 to 1600° C. The sintered product thus obtained is ball-milled in water and then subjected to washing, separating and drying steps. Finally, the resultant product is sieved so as to make uniform the central particle diameter of the product. Usually, the particles of fluorescent substance are regulated to fall within the range of 10 to 20 μm in particle size distribution (central particle diameter). In this embodiment however, the particle size distribution is not restricted to this range. Namely, it is permissible as long as the particle size distribution of the fluorescent substance is confined to 75 μm or less.

Next, the fluorescent substance obtained from the aforementioned steps is incorporated into a light-transmitting material (for example, silicone resin, etc.) at a concentration ranging, for example, from 40 to 60 wt % and then stirred for 5 minutes in an autorotation/revolution mixer. Then, in order to cool down the heat generated from the stirring treatment, the fluorescent substance is left to stand for 30 minutes to turn the resin back to normal temperature to stabilize the resin. The mixed liquid thus obtained is then transferred to a cylinder.

The mixed liquid is further left to stand in vacuum to remove the air entrapped in the mixed liquid. Subsequently, the fluorescent substance-containing resin thus prepared is dripped onto the LED chip 3 mounted on the mounting substrate 1 using dispenser, thus filling the concave portion with the resin. This filling is performed so as to confine the final thickness of the fluorescent layer to the range of 80 to 240 μm. If required, the mounting substrate 1 or the LED chip 3 may be heated to lower the viscosity of the fluorescent substance-containing resin.

Finally, the fluorescent substance-containing resin is heat-treated to form a resin layer on the LED chip 3. The heating temperature to be employed in this case may be suitably selected depending on the curing temperature of the light-transmitting material. It is required in this case to heat the fluorescent substance-containing resin at least up to a temperature which is needed to cure the fluorescent substance-containing resin. For example, when silicone resin is to be employed as the light-transmitting material, the heating may be performed at a temperature ranging from 80 to 200° C. for 30 minutes to 3 hours for curing the silicone resin.

Incidentally, when the aforementioned light-transmitting material (for example, silicone resin) is coated by an inkjet method, the quantity of resin can be finely adjusted and the configuration of resin can be delicately controlled, thus making it possible to perform finer adjustment of chromaticity.

One of most important features of the embodiment of the present invention resides in the finding of facts that have been first found out by the present inventor, i.e., the facts that a resin containing the aforementioned fluorescent substance at a predetermined concentration exhibits a different surface tension to the electrode 2a (metal) from that to an upper surface portion (mainly constituted by an insulating material) of the mounting substrate 1, which is disposed around the electrode 2a, and that, based on this phenomenon, it is possible to selectively form the fluorescent layer 4 on the surface of electrode 2a without depositing the fluorescent layer 4 on the upper surface of the mounting substrate 1.

Accordingly, by designing the planar configuration of the electrode 2a so as to make it correspond with the far-field pattern 16 of the light to be emitted from the upper surface of LED chip 3 and from four sides, it is possible to make the planar configuration of the fluorescent layer 4 correspond with the far-field pattern 16, thus enabling the fluorescent layer 4 to be disposed in a manner that the intensity distribution of the light emitted from the LED chip 3 can be well reflected. Because of this, the fluorescent layer 4 having a desired planar configuration (for example, nearly parabolic or arc in configuration) can be conveniently and inexpensively formed with excellent reproducibility without necessitating the employment of a special mold.

Incidentally, if required, the fluorescent layer 4 may be formed also on the LED chip 3. In this case, the concentration of fluorescent substance incorporated in a resin, the viscosity of the resin, the quantity of the resin, etc. are suitably regulated in the step of forming the fluorescent layer 4 on the LED chip 3.

Next, if required, a reflective film 7 is deposited on the inner surface of the sidewall 6. This reflective film 7 can be formed by evaporation, printing, plating, etc., using a metal which is excellent in reflectance such as silver, gold or aluminum. Further, if required, resin such as silicone resin or a material such as glass may be embedded in a space 8 inside the concave portion. Thereafter, in order to seal the space 8, a cover board 9 is adhered to the opening of the sidewall 6, thus accomplishing the light-emitting device.

Incidentally, in order to enhance the reliability of the light-emitting device, the gap formed between the LED chip 3 and the mounting substrate 1 may be filled with an underfill. As the material for the underfill, it is possible to employ a thermosetting resin such as epoxy resin. In order to alleviate the thermal stress of the underfill, it may be mixed the epoxy resin with aluminum nitride, aluminum oxide or a composite mixture of these materials. The quantity of the underfill may be such that the gap generated between the mounting substrate 1 and both positive and negative electrodes of the LED chip 3 can be sufficiently filled with the underfill.

### Second Embodiment

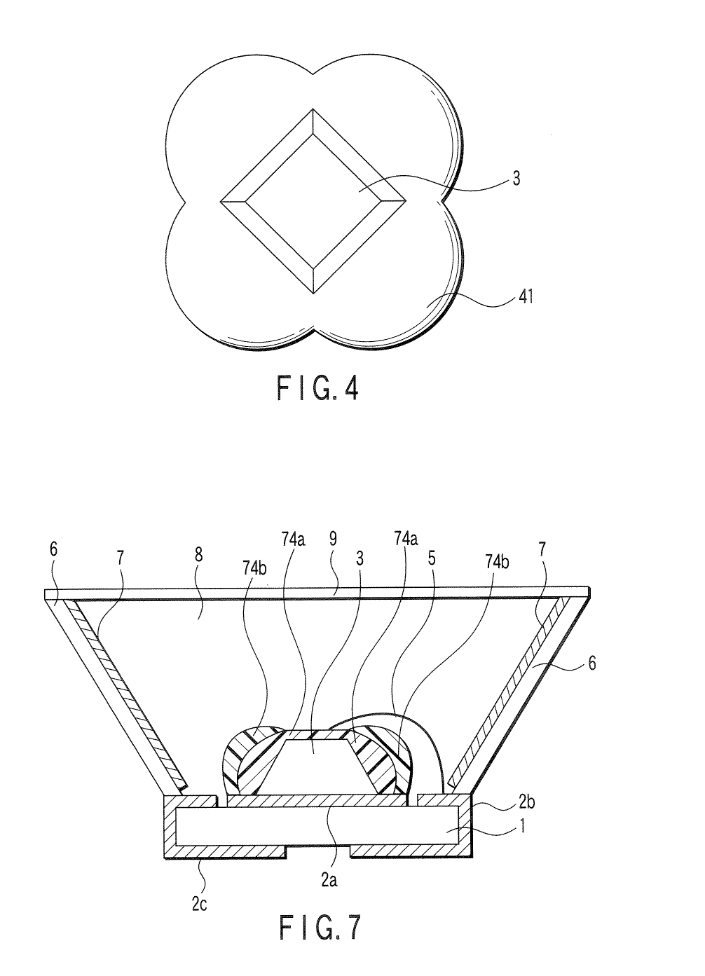

A second embodiment will be explained as follows. The white LED according to this embodiment shown in FIG. 4 differs from the white LED of the first embodiment in terms of the configuration of the electrode 41 below the LED chip 3.

As shown in FIG. 4, according to the white LED of this embodiment, the planar configuration of the electrode 41 is made to correspond with a near-field pattern of the light to be emitted from the LED chip 3. Namely, this electrode 41 has a planar pattern having four projected portions which are made to correspond with four sides of the planar configuration of the LED chip 3. Each of these projected portions is formed to have nearly a parabolic or arc peripheral profile. In order to make the configuration of the electrode 2a correspond with the configuration of the near-field pattern, the electrode 41 is made slightly larger than the LED chip 3.

Specifically, the size of this electrode 41 is smaller than that of the first embodiment. Namely, the electrode 41 may be designed to have a size (a distance between the opposite apexes of the parabolic or circular peripheral profile) which is about 0.1 to one time as large as the outer diameter (in the direction parallel to one of the sides of LED chip 3) of the LED chip 3.

In this embodiment also, the planar configuration of the fluorescent layer 4 is made to correspond with the planar configuration of the electrode 41. Namely, since the planar configuration of the fluorescent layer 4 is formed to correspond with the near-field pattern, it is now possible to make the intensity distribution of the light emitted from the LED chip 3 correspond exactly with the density distribution of the fluorescent substance in the fluorescent layer 4. Thus, the fluorescent layer 4 can be disposed in a manner that the intensity distribution of the light emitted from the LED chip 3 can be reliably reflected, while inhibiting any wasting of light in the conversion of light. Therefore, it is possible to obtain a white LED which is negligible in non-uniformity of color and uniform in light-emitting pattern.

### Third Embodiment

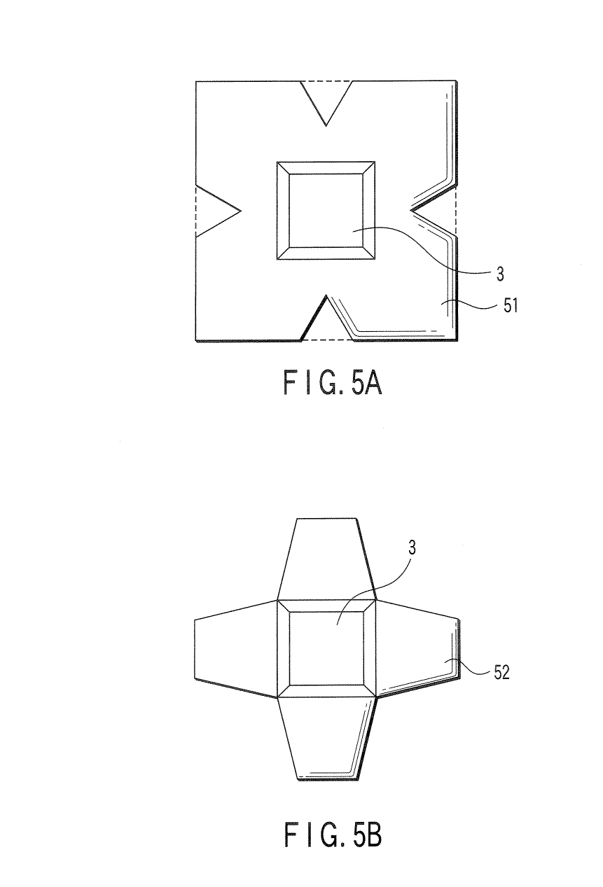

A third embodiment will be explained as follows. The white LED according to this embodiment shown in FIGS. 5A and 5B differs from the white LED of the first and second embodiments in terms of the configuration of the electrodes 51 and 52 below the LED chip 3.

As shown in FIG. 5A, according to the white LED of this embodiment, the planar configuration of the electrode 51 is made to approximately correspond with a far-field pattern of the light to be emitted from the LED chip 3. Namely, this electrode 51 has a planar pattern having four projected portions which are made to correspond with four apexes of the planar configuration of the LED chip 3. The profile of each of these four projected portions is constituted by four sides. Namely, this projected portion is formed of a pentagonal configuration. These four projected portions can be formed as follows. Specifically, a rectangular (especially, square) electrode pattern is formed at first and then, a central portion of each of four sides of this electrode pattern is etched away to form a triangular (especially, isosceles triangle) cut-out portion, respectively.

In this manner, the electrode 51 having a planar configuration which is similar to the far-field pattern can be conveniently formed. Incidentally, the projected portion of the electrode 51 may not be limited to the pentagonal configuration as shown in FIG. 5A but may be any other polygonal configurations. As the configuration of the cut-out portion also, it may not be limited to the triangular configuration as shown in FIG. 5A but may be any other polygonal configurations. The polygonal configuration in this case means an n-gon (n is 3 or more).

Further, as shown in FIG. 5B, the planar configuration of the electrode 52 may be made to correspond with a near-field pattern of the light to be emitted from the LED chip 3. Namely, this electrode 52 has a planar pattern having four projected portions which are made to correspond with four sides of the planar configuration of the LED chip 3. Each of these four projected portions is constituted by three sides. Namely, this projected portion is quadrangular. The planar configuration of this electrode 52 can be conveniently fabricated.

Incidentally, the projected portion of the electrode 52 may not be restricted to a quadrangular configuration, but may be n-gon (n is 3 or more).

### Fourth Embodiment

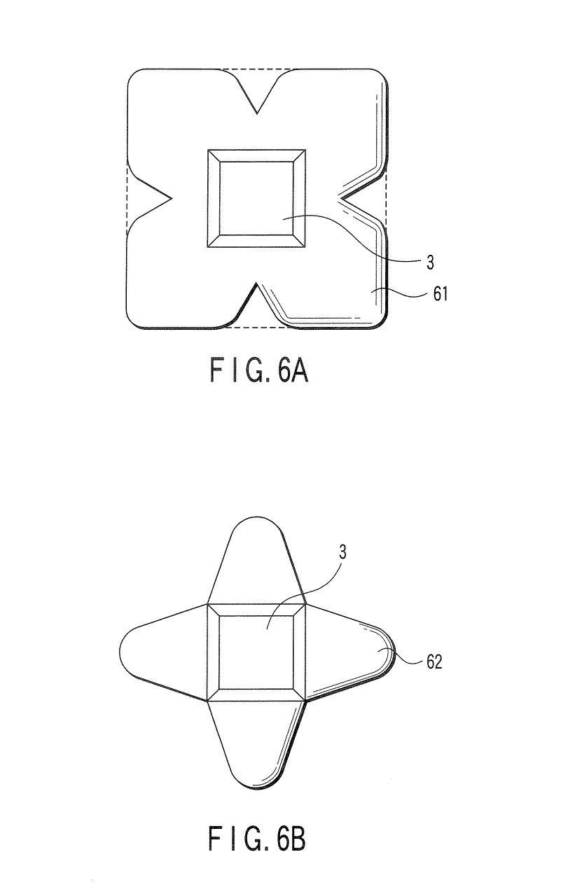

A fourth embodiment will be explained as follows. The white LED according to this embodiment shown in FIGS. 6A and 6B differs from the white LED of the third embodiment in terms of the configuration of the electrodes 61 and 62 disposed the LED chip 3.

As shown in FIGS. 6A and 6B, the planar configurations of these electrodes 61 and 62 is almost the same as the planar configurations of these electrodes 51 and 52 shown in FIGS. 5A and 5B except that the corner portions of projected portions are rounded. By modifying these corner portions in this manner, the resin containing a fluorescent substance can be easily coated exactly along the corner portions of the projected portions in the planar configuration of the electrodes 61 and 62. As a result, the fluorescent layer 4 can be formed to have a configuration which is much closer to the far-field pattern or near-field pattern of the light to be emitted from the LED chip 3.

Incidentally, the recessed corner portions between the projected portions of these electrodes 61 and 62 may be also rounded likewise, thereby making it also possible to make the planar configuration of the fluorescent layer 4 much closer to the far-field pattern or near-field pattern.

### Fifth Embodiment

A fifth embodiment will be explained as follows. The white LED according to this embodiment shown in FIG. 7 differs from the white LED of the first embodiment in that a combination of an inorganic fluorescent layer and an organic fluorescent layer is employed as a fluorescent layer in this embodiment.

As shown in FIG. 7, an inorganic fluorescent layer 74a is selectively formed on the electrode 2a and extended therefrom to cover the side and upper surface of the LED chip 3. An organic fluorescent layer 74b is also selectively formed on the electrode 2a and extended therefrom to partially cover the inorganic fluorescent layer 74a. Although the organic fluorescent layer 74b is formed so as to cover only the side of the LED chip 3, the organic fluorescent layer 74b also may be formed so as to cover the upper surface of the LED chip 3.

According to the white LED of this embodiment, since a combination of an inorganic fluorescent layer and an organic fluorescent layer is employed as a fluorescent layer, it is possible to obtain white light which is more excellent in color rendering. Namely, for example, when a gallium nitride-based semiconductor light-emitting element emitting blue light is employed as the LED chip 3, the yellow fluorescent substance described in the first embodiment may be employed as a fluorescent substance to be included in the inorganic fluorescent layer 74a and mixed, for example, with silicone resin, and a red color type rare earth metal complex may be employed as a fluorescent substance to be included in the organic fluorescent layer 74b and mixed, for example, with fluorinated resin, thus making it possible to obtain white light excellent in color rendering. As an example of the rare earth metal complex, it is possible to employ a complex wherein a phosphine oxide compound or an acetylacetonato derivative (β-diketone derivative) is coordinated to a rare earth metal ion such as Eu ion as shown in the following chemical formula (1) can be employed.

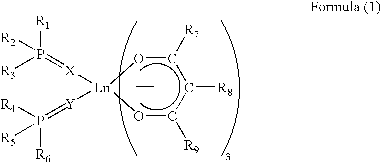

(wherein, X and Y may be the same or different and are individually an atom selected from the group consisting of O, S and Se (especially, O); and R₁-R₆ may be the same or different and are individually a group selected from the group consisting of linear or branched alkyl or alkoxy group having 20 or more carbon atoms, phenyl group, biphenyl group, naphthyl group, heterocyclic group and a substituted group comprising any of these groups, wherein a combination of R₁-R₃ may be the same with a combination of R₄-R₆ but preferably be different from a combination of R₄-R₆ in terms of emission intensity (for example, R₁-R₃ may be individually n-Oc (octyl) group and R₄-R₆ may be individually phenyl group); Ln is rare earth element (Eu or other element such as Tb or Er as described hereinafter); R₇ and R₉ may be the same or different and are individually a group selected from the group consisting of linear or branched alkyl or alkoxy group, phenyl group, biphenyl group, naphthyl group, heterocyclic group and a substituted group comprising any of these groups (for example, n-C₄F₉ or t-C₄F₉); and R₈ is halogen atom, deuterium atom or linear or branched aliphatic group having 1 to 22 carbon atoms).

This rare earth metal complex is large in fluorescence intensity. In particular, when plural kinds (especially, two kinds) of phosphorus compounds differing in structure in the above-described chemical formula (1) are coordinated to one rare earth metal atom, the ligand field thereof becomes more asymmetrical and the molecular extinction coefficient thereof would be enhanced, thus remarkably increasing the emission intensity.

Incidentally, it is also possible to adopt a structure wherein the inorganic fluorescent layer 74a is formed on the organic fluorescent layer 74b.

### Sixth Embodiment

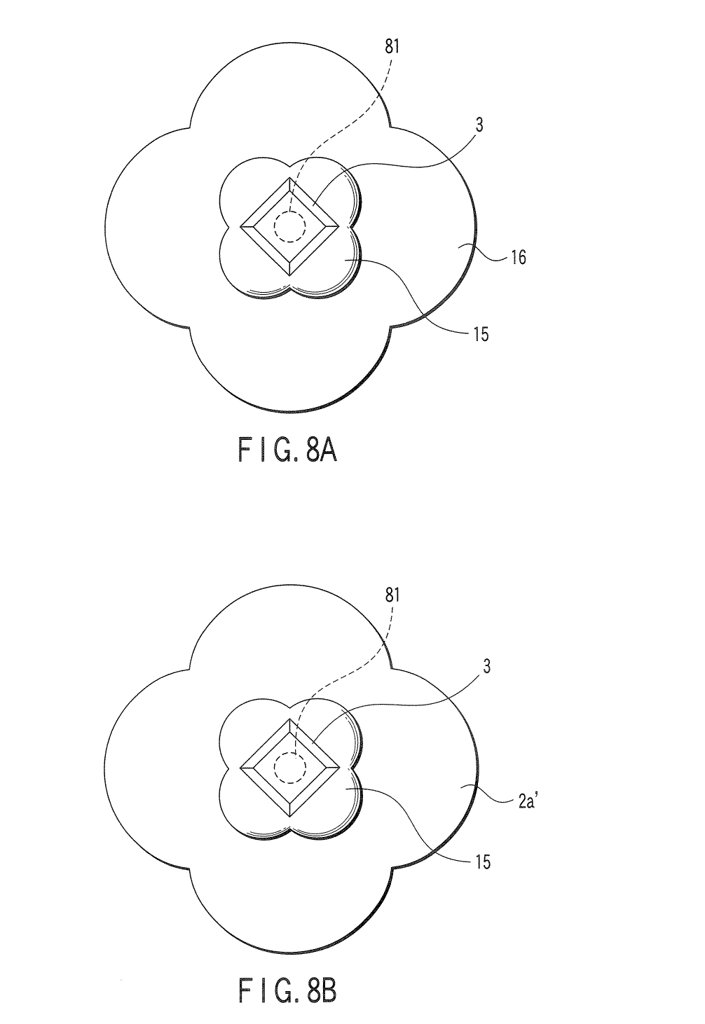

A sixth embodiment will be explained as follows. The white LED according to this embodiment shown in FIG. 8A differs from the white LED of the first embodiment in terms of the configuration of the electrode below the LED chip 3.

In the embodiment shown in FIG. 8B, the configuration of the electrode 2a′ below the LED chip 3 is created such that a circular opening 81 is disposed directly below the center of the LED chip 3. In the light-emitting device of the embodiments, one of important features thereof resides in the fact that part of the metal layer disposed below the light-emitting element is protruded and exposed from the periphery of the light-emitting element, and hence the metal layer may not necessarily be provided so as to entirely face all of the underside of the light-emitting element. Although a circular opening 81 is formed in the electrode 2a′ in this embodiment, the configuration of the opening may not be circular but may be of any other configuration. For example, the opening may be a slit-like opening.

### Seventh Embodiment

A seventh embodiment will be explained as follows. The white LED according to this embodiment differs from the white LED of the first embodiment in that the organic fluorescent layer explained in the fifth embodiment is embedded throughout the concave portion of the mounting substrate 1. Namely, referring to FIG. 1A, the organic fluorescent layer explained in the fifth embodiment is embedded in the space 8 inside the concave portion of the mounting substrate 1.

According to this embodiment, it is possible to minimize the non-uniformity of color as in the case of the first embodiment and also to obtain a white LED which is uniform in emission pattern. Although the planar configuration of the organic fluorescent layer is not formed into a pattern which corresponds with the far-field pattern or the near-field pattern, it would not give any substantial influence to the generation of non-uniformity of emission intensity or of non-uniformity of color, since the distance from the LED chip 3 is far remote as compared with that of the inorganic fluorescent layer 4 and the non-uniformity in distribution of light-emitting pattern is minimized.

### Eighth Embodiment

A eighth embodiment will be explained as follows.

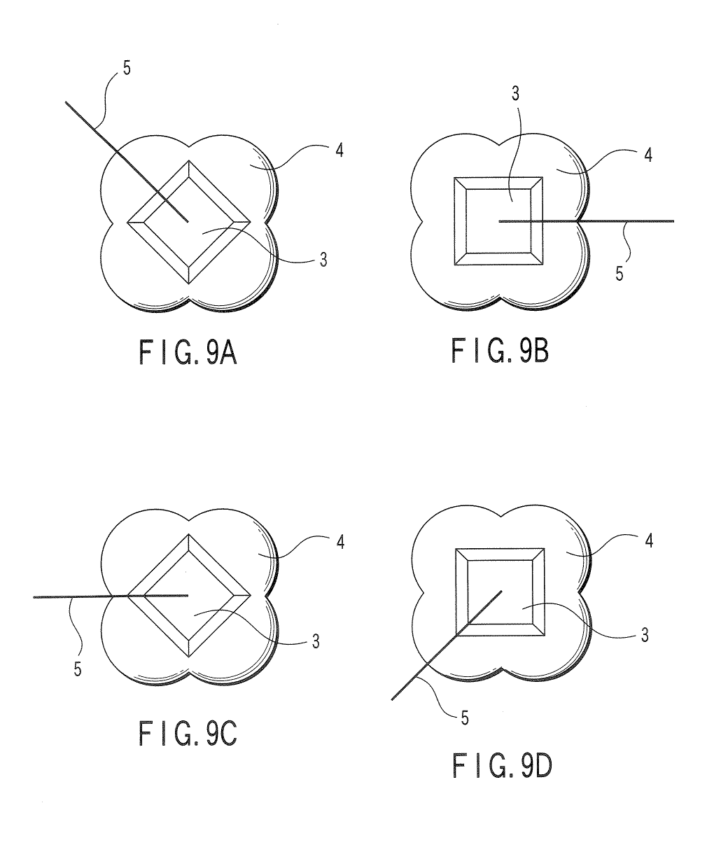

In the embodiments shown in FIGS. 9A and 9B, the planar configuration of the fluorescent layer 4 is made to correspond with the near-field pattern of the light to be emitted from the LED chip 3. In the arrangement shown in FIG. 9A, the bonding wire 5 is extended out of the chip from the central portion of one side of the LED chip 3. Namely, the bonding wire 5 is extended out passing over a thickest portion of the fluorescent layer 4. On the other hand, in the arrangement shown in FIG. 9B, the bonding wire 5 is extended out of the chip from one corner portion of the LED chip 3. Namely, the bonding wire 5 is extended out passing over a thinnest portion of the fluorescent layer 4. In the case of the structure where the bonding wire 5 is extended out passing over a thinnest portion of the fluorescent layer 4, the bonding wire 5 is extended out avoiding the region where the emission intensity is relatively large, thereby making it possible to efficiently retrieve the light form the LED chip 3.

In the embodiments shown in FIGS. 9C and 9D, the planar configuration of the fluorescent layer 4 is made to correspond with the far-field pattern of the light to be emitted from the LED chip 3. In the arrangement shown in FIG. 9C, the bonding wire 5 is extended out of the chip from the central portion of one side of the LED chip 3. Namely, the bonding wire 5 is extended out passing over a thinnest portion of the fluorescent layer 4. On the other hand, in the arrangement shown in FIG. 9D, the bonding wire 5 is extended out of the chip from one corner portion of the LED chip 3. Namely, the bonding wire 5 is extended out passing over a thickest portion of the fluorescent layer 4. In this case also, in the case of the structure where the bonding wire 5 is extended out passing over a thinnest portion of the fluorescent layer 4, the bonding wire 5 is extended out avoiding the region where the emission intensity is relatively large, thus making it possible to efficiently retrieve the light out of the LED chip 3.

Incidentally, the present invention should not be construed as limited to the foregoing embodiments or examples. For example, the substrate for forming the LED chip 3 may be formed of other materials. For example, it is possible to employ a laminated substrate comprising YAG and Al₂O₃ (sapphire) or to employ a substrate comprising Al₂O₃ (sapphire) in which YAG is incorporated.

Further, it is also possible, other than the fluorescent substance, to employ a coloring agent in a wavelength-converting layer. For example, it is possible to employ, as a coloring agent, neodymium oxide as a red coloring agent, chromium oxide as a green coloring agent, copper oxide as a blue coloring agent, and holmium oxide as a yellow coloring agent.

As the fluorescent substance, it is possible to employ various fluorescent substances which emits light as they are excited by the light to be emitted from a semiconductor LED chip. When a blue LED chip is employed together with a yellow fluorescent substance, it is possible to obtain white light. This fluorescent substance may be mixed with a red fluorescent substance or a yellowish green fluorescent substance. When these fluorescent substances are mixed with each other, the color rendering can be enhanced. Alternatively, an ultraviolet LED chip may be employed in combination with the aforementioned fluorescent substances and also with a blue fluorescent substance. The light-emitting device according to embodiments of the present invention is applicable to any optional fluorescent substance exhibiting any of various wavelengths.

As the fluorescent substance which emits red color, it is possible to employ an europium-activated alkaline earth metal silicate-based fluorescent substance represented by (Ba, Ca, Sr)₂SiO₄:Eu. When Ba is substituted for part of Sr, the emission spectrum of the fluorescent substance can be shifted toward the short wavelength side, and when Ca is substituted for part of Sr, the emission spectrum of the fluorescent substance can be shifted toward the long wavelength side. By changing the composition in this manner, the emission color can be sequentially regulated.

It is also possible to employ a nitride fluorescent substance containing: at least one selected from the group consisting of Be, Mg, Ca, Sr, Ba and Zn; and at least one selected from the group consisting of C, Si, Ge, Sn, Ti, Zr and Hf; this nitride fluorescent substance being activated by at least one selected from rare earth elements. It is also possible to employ an europium-activated alkaline earth silicon nitride-based fluorescent substance represented by (Mg, Ca, Sr, Ba)₂Si₅N₈:Eu and constituted by fractured particles having a red rupture cross-section, thus enabling it to emit light of red region, or to employ an europium-activated rare earth oxychalcogenide-based fluorescent substance represented by (Y, La, Gd, Lu)₂O₂S:Eu and constituted by approximately spherical growth particles as a configuration of regular crystal growth, thus enabling it to emit light of red region.

As the fluorescent substance which emits green color, it is possible to employ an europium-activated alkaline earth silicon oxynitride-based fluorescent substance represented by (Mg, Ca, Sr, Ba)Si₂O₂N₂:Eu and constituted by fractured particles having a rupture cross-section, thus enabling it to emit light of green region, or to employ an europium-activated alkaline earth magnesium silicate-based fluorescent substance represented by (Ba, Ca, Sr)₂SiO₄:Eu and constituted by fractured particles having a rupture cross-section, thus enabling it to emit light of green region.

As the fluorescent substance which emits blue color, it is possible to employ a fluorescent substance represented by (Sr, Ca)₁₀(PO₄)₆Cl₂:Eu²⁺ or a fluorescent substance represented by BaMg₂Al₁₆O₂₇:Eu²⁺.

These fluorescent substances mentioned above may be employed singly or in combination of two or more. Further, these fluorescent substances can be suitably employed in combination with a light-emitting element to obtain any desired color tone. For example, when a semiconductor light-emitting element emitting blue color is employed in combination with a yellow fluorescent substance, it is possible to obtain a light-emitting device which emits white light. However, when this fluorescent substance is replaced by a mixture containing a yellow fluorescent substance and a red fluorescent substance in this case, it is possible to obtain a light-emitting device which emits white light of warm color.

It is possible to obtain a desired light of whitish mixed color by suitably mixing two or more fluorescent substances. More specifically, by suitably adjusting the mixing ratio of a plurality of fluorescent substances differing in chromaticity from each other in conformity with the emission wavelength of light-emitting chip in the preparation of a mixture of fluorescent substances, it is possible to obtain a light-emitting device which emits light at any desired point in the chromaticity diagram representing the relationship between a combination of fluorescent substances and the light-emitting chip.

The present invention should not be construed as being limited to the foregoing embodiments and examples. Namely, the constituent elements can be variously modified in practicing the present invention within the scope of the invention. Further, a plurality of constituent elements disclosed in the foregoing embodiments and examples may be optionally combined to create various forms of invention. For example, some of the constituent elements illustrated in the foregoing embodiments and examples may be eliminated. Furthermore, the constituent elements illustrated in different embodiments and examples described above may be optionally combined.

According to the present invention, it is possible to provide a light-emitting device which is capable of obtaining a uniform chromaticity and a uniform emission intensity, and to provide a method of manufacturing a light-emitting device having such features.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A light-emitting device comprising:
a substrate;
a light-emitting element configured to emit light having a first wavelength, the light-emitting element having a pair of electrodes and being formed above the substrate;
a metal layer interposed between the substrate and the light-emitting element and having a planar configuration, a periphery of which is at least partially constituted by a plurality of projected portions and a plurality of recessed portions, the plurality of projected portions being located outside of the light-emitting element; and
a wavelength converting layer formed on the metal layer, the wavelength converting layer absorbing at least part of the light emitted from the light-emitting element and converting the first wavelength, thereby light having a second wavelength differing in wavelength from the first wavelength being emitted.

2. The light-emitting device according to claim 1, wherein each of the projected portions of the planar configuration of the metal layer is a polygonal shape.

3. The light-emitting device according to claim 1, wherein each of the recessed portions of the planar configuration of the metal layer is a polygonal shape.

4. The light-emitting device according to claim 1, wherein each of the projected portions of the planar configuration of the metal layer is defined by a curve.

5. The light-emitting device according to claim 1, wherein each of the projected portions of the planar configuration of the metal layer is defined by an arc.

6. The light-emitting device according to claim 1, wherein the wavelength converting layer has a planar configuration having an outer peripheral profile which is substantially identical with that of the metal layer.

7. The light-emitting device according to claim 1, wherein the metal layer is a first electrode to which one of the pair of electrodes of the light-emitting element being connected.

8. The light-emitting device according to claim 1, wherein the wavelength converting layer is additionally provided on the light-emitting element.

9. The light-emitting device according to claim 7, further comprising a second electrode provided on the substrate, and a bonding wire connecting the other of the pair of electrodes of the light-emitting element to the second electrode.

10. The light-emitting device according to claim 9, wherein the wavelength converting layer has a thickest portion and a thinnest portion, the bonding wire is provided to pass over the thickest portion of the wavelength converting layer.

11. The light-emitting device according to claim 9, wherein the wavelength converting layer has a thickest portion and a thinnest portion, the bonding wire is provided to pass over the thinnest portion of the wavelength converting layer.

12. The light-emitting device according to claim 1, wherein the wavelength converting layer comprises a fluorescent substance.

13. A light-emitting device comprising:
a substrate;
a light-emitting element configured to emit light having a first wavelength and accompanied with a far-field pattern and a near-field pattern, the light-emitting element having a pair of electrodes and being formed above the substrate;
a metal layer interposed between the substrate and the light-emitting element and having a planar configuration, the periphery of which is at least partially constituted by a pattern corresponding to the far-field pattern or the near-field pattern of the light emitted from the light-emitting element; and
a wavelength converting layer formed on the metal layer, the wavelength converting layer absorbing at least part of the light emitted from the light-emitting element and converting the first wavelength, thereby light having a second wavelength differing in wavelength from the first wavelength being emitted.

14. The light-emitting device according to claim 13, wherein the wavelength converting layer has a planar configuration having an outer peripheral profile which is substantially identical with that of the metal layer.

15. The light-emitting device according to claim 13, wherein the metal layer is a first electrode to which one of the pair of electrodes of the light-emitting element being connected.

16. The light-emitting device according to claim 13, wherein the wavelength converting layer is additionally provided on the light-emitting element.

17. The light-emitting device according to claim 15, further comprising a second electrode provided on the substrate, and a bonding wire connecting the other of the pair of electrodes of the light-emitting element to the second electrode.

18. The light-emitting device according to claim 17, wherein the wavelength converting layer has a thickest portion and a thinnest portion, the bonding wire is provided to pass over the thickest portion of the wavelength converting layer.

19. The light-emitting device according to claim 17, wherein the wavelength converting layer has a thickest portion and a thinnest portion, the bonding wire is provided to pass over the thinnest portion of the wavelength converting layer.

20. The light-emitting device according to claim 13, wherein the wavelength converting layer comprises a fluorescent substance.

21. A method for manufacturing a light-emitting device comprising:
forming a metal layer on a substrate;
working the metal layer to form a patterned metal layer having a planar configuration, a periphery of which is at least partially constituted by a plurality of projected portions and a plurality of recessed portions;
mounting a light-emitting element at a center of the patterned metal layer, the light-emitting element being configured to emit light having a first wavelength;
dripping a raw material containing fluorescent substance from over the light-emitting element to selectively form a wavelength converting layer on the surfaces of the patterned metal layer and the light-emitting element or on the surface of the patterned metal layer, the wavelength converting layer absorbing at least part of the light emitted from the light-emitting element and converting the first wavelength, thereby light having a second wavelength differing in wavelength from the first wavelength being emitted.

22. The method according to claim 21, wherein dripping the raw material containing the fluorescent substance is performed by an inkjet method.
